(19) United States
(12) Patent Application Publication
(10) Pub. No.: US 2026/0293714 A1
(43) Pub. Date: Sep. 24, 2026

(54) PACKAGING STRUCTURE AND MANUFACTURING METHOD THEREOF

(71) Applicant: Yangtze Memory Technologies Co., Ltd., Wuhan (CN)

(72) Inventors: Meng WANG, Wuhan (CN); Baohua ZHANG, Wuhan (CN); Duantao WANG, Wuhan (CN); Xinru ZENG, Wuhan (CN)

(21) Appl. No.: 19/413,882

(22) Filed: Dec. 9, 2025

(30) Foreign Application Priority Data
Mar. 19, 2025 (CN) 202510329123.8

(51) Int. Cl. H10W 70/60; H10W 70/65; H10W 74/10; H10W 90/24

(52) U.S. Cl. CPC H10W 70/611; H10W 70/65; H10W 74/117; H10W 90/24

(57) ABSTRACT

The present disclosure provides a packaging structure and a manufacturing method thereof. The packaging structure includes: a substrate including a first wiring layer; one or more adapter boards located on a first side of the substrate, each adapter board including a respective second wiring layer connected to the first wiring layer, the one or more adapter boards including a first adapter board; and one or more stacks located on the first side of the substrate. Each stack includes one or more chips, and the one or more stacks include a first stack connected to a second wiring layer in the first adapter board. The one or more stacks and the one or more adapter boards are arranged along a direction perpendicular to a thickness direction of the substrate.

### CROSS-REFERENCE TO RELATED APPLICATIONS

This application claims priority to Chinese Patent Application No. 202510329123.8, filed on Mar. 19, 2025, which is hereby incorporated by reference in its entirety.

### FIELD OF TECHNOLOGY

The present disclosure relates to the field of semiconductor technology, and in particular, to a packaging structure and a manufacturing method thereof.

### BACKGROUND

Chip packaging is an important aspect of semiconductor processes. Multiple integrated circuits are packaged into a single packaging structure to enable chip integration. For different packaging structures, different packaging substrates used are designed differently.

### SUMMARY

According to one aspect of the present disclosure, a packaging structure is provided, comprising: a substrate comprising a first wiring layer; one or more adapter boards located on a first side of the substrate, each adapter board comprising a second wiring layer connected to the first wiring layer, and the one or more adapter boards comprising a first adapter board; and one or more stacks located on the first side of the substrate, each stack comprising one or more chips, the one or more stacks comprising a first stack connected to the second wiring layer in the first adapter board, wherein an arrangement direction of the one or more stacks and the one or more adapter boards is perpendicular to a thickness direction of the substrate.

In some examples, the one or more adapter board further comprises a second adapter board, and the one or more stacks further comprise a second stack connected to a second wiring layer in the second adapter board.

In some examples, the one or more stacks further comprise a second stack connected to a second wiring layer in the first adapter board.

In some examples, the substrate further comprises a plurality of first pads located between the first wiring layer and the one or more adapter boards and connected to the first wiring layer, each adapter board further comprises a plurality of second pads and a plurality of third pads, the plurality of second pads are located between the second wiring layer and the substrate, the plurality of second pads are connected to the second wiring layer and connected to the plurality of first pads, the second wiring layer is located between the plurality of third pads and the substrate, and the plurality of third pads are connected to the second wiring layer and the one or more stacks.

In some examples, the packaging structure further comprises a first lead connected to the plurality of third pads and the one or more stacks.

In some examples, the packaging structure further comprises: an encapsulation layer covering the one or more adapter boards and the one or more stacks; and a plurality of metal bumps on a second side of the substrate and connected to the first wiring layer, wherein the second side is opposite to the first side.

In some examples, the adapter board comprises a printed circuit board, an interposer, or another substrate.

According to another aspect of the present disclosure, a packaging structure is provided, comprising: a substrate comprising a first wiring layer; one or more adapter boards located on a first side of the substrate, each adapter board comprising a second wiring layer connected to the first wiring layer, the one or more adapter boards comprising a first adapter board; one or more stacks located on the first side of the substrate, each stack comprising one or more first chips, the one or more stacks comprising a first stack connected to a second wiring layer in the first adapter board, wherein an arrangement direction of the one or more stacks and the one or more adapter boards is perpendicular to a thickness direction of the substrate; and a second chip connected to the second wiring layer in the first adapter board, wherein the first adapter board is located between the second chip and the substrate.

In some examples, the one or more adapter board further comprises a second adapter board, and the one or more stacks further comprise a second stack connected to a second wiring layer in the second adapter board.

In some examples, the one or more stacks further comprise a second stack connected to a second wiring layer in the first adapter board.

In some examples, the substrate further comprises a plurality of first pads located between the first wiring layer and the one or more adapter board boards and connected to the first wiring layer, each adapter board further comprises a plurality of second pads and a plurality of third pads, the plurality of second pads are located between the second wiring layer and the substrate, the plurality of second pads are connected to the second wiring layer and connected to the plurality of first pads, the second wiring layer is located between the plurality of third pads and the substrate, and the plurality of third pads are connected to the second wiring layer and the one or more stacks.

In some examples, the packaging structure further comprises a first lead connected to the plurality of third pads and the one or more stacks.

In some examples, the packaging structure further comprises a second lead connected to the second chip and a second wiring layer in the first adapter board.

In some examples, the packaging structure further comprises a flip-chip structure located between the second chip and the first adapter board and connected to the second chip and a second wiring layer in the first adapter board.

In some examples, the flip-chip structure comprises: a fourth pad located between the second chip and a second wiring layer in the first adapter board; and a filler layer filled around the fourth pad.

In some examples, the packaging structure further comprises: an encapsulation layer covering the one or more adapter boards, the one or more stacks, and the second chip; and a plurality of metal bumps located on a second side of the substrate and connected to the first wiring layer, wherein the second side is opposite to the first side.

In some examples, the first chip is a memory chip, and the second chip is a control chip.

According to another aspect of the present disclosure, a manufacturing method for a packaging structure is provided, comprising: obtaining a substrate and one or more adapter boards, wherein the substrate comprises a first wiring layer, each adapter board comprises a second wiring layer, and the one or more adapter boards comprise a first adapter board; disposing the one or more adapter boards on a first side of the substrate, wherein the second wiring layer is connected to the first wiring layer; disposing one or more stacks on a first side of the substrate, each stack comprising one or more first chips, the one or more stacks comprising a first stack, wherein an arrangement direction of the one or more stacks and the one or more adapter boards is perpendicular to a thickness direction of the substrate; and connecting the first stack to a second wiring layer in the first adapter board.

In some examples, connecting the first stack to the second wiring layer in the first adapter board comprises: connecting the first stack to the second wiring layer in the first adapter board using a first lead.

In some examples, the manufacturing method further comprises: disposing a second chip on a side of the first adapter board away from the substrate, and connecting the second chip to the second wiring layer of the first adapter board.

In some examples, connecting the second chip to the second wiring layer of the first adapter board comprises: connecting the second chip to the second wiring layer of the first adapter board using a second lead or a flip-chip structure.

In some examples, the manufacturing method further comprises: forming an encapsulation layer covering the one or more adapter boards and the one or more stacks; and disposing a plurality of metal bumps on a second side of the substrate, wherein the plurality of metal bumps are connected to the first wiring layer, and the second side is opposite to the first side.

Other features and advantages of the present disclosure will become apparent from the following detailed description of exemplary examples of the present disclosure with reference to the accompanying drawings.

### BRIEF DESCRIPTION OF THE DRAWINGS

The accompanying drawings that form part of the specification describe examples of the present disclosure and together with the description serve to explain the principles of the present disclosure.

The present disclosure may be more clearly understood from the following detailed description with reference to the accompanying drawings, in which:

FIG. 1A is a cross-sectional view schematically illustrating a packaging structure according to some examples of the present disclosure;

FIG. 1B is an enlarged cross-sectional view schematically illustrating an adapter board according to some examples of the present disclosure;

FIG. 2 is a cross-sectional view schematically illustrating a packaging structure according to some other examples of the present disclosure;

FIG. 3 is a cross-sectional view schematically illustrating a packaging structure according to some other examples of the present disclosure;

FIG. 4 is a cross-sectional view schematically illustrating a packaging structure according to some other examples of the present disclosure;

FIG. 5 is a cross-sectional view schematically illustrating a packaging structure according to some other examples of the present disclosure;

FIG. 6 is a cross-sectional view schematically illustrating a packaging structure according to some other examples of the present disclosure;

FIG. 7 is a flowchart illustrating a manufacturing method for a packaging structure according to some examples of the present disclosure;

FIG. 8A is a cross-sectional view schematically illustrating a structure at a stage in a manufacturing process of a packaging structure according to some examples of the present disclosure;

FIG. 8B is a top view schematically illustrating a structure at a stage in a manufacturing process of a packaging structure according to some examples of the present disclosure;

FIG. 8C is a schematic cross-sectional view schematically illustrating another structure at a stage in a manufacturing process of a packaging structure according to some examples of the present disclosure;

FIG. 8D is a top view schematically illustrating another structure at a stage in a manufacturing process of a packaging structure according to some examples of the present disclosure;

FIG. 9 is a cross-sectional view schematically illustrating a structure at another stage in a manufacturing process of a packaging structure according to some examples of the present disclosure;

FIG. 10 is a cross-sectional view schematically illustrating a structure at another stage in a manufacturing process of a packaging structure according to some examples of the present disclosure;

FIG. 11 is a cross-sectional view schematically illustrating a structure at another stage in a manufacturing process of a packaging structure according to some examples of the present disclosure;

FIG. 12 is a cross-sectional view schematically illustrating a structure at another stage in a manufacturing process of a packaging structure according to some examples of the present disclosure;

FIG. 13A is a cross-sectional view schematically illustrating a structure at a stage in a manufacturing process of a packaging structure according to some other examples of the present disclosure;

FIG. 13B is a top view schematically illustrating a structure at a stage in a manufacturing process of a packaging structure according to some other examples of the present disclosure;

FIG. 13C is a cross-sectional view schematically illustrating another structure at a stage in a manufacturing process of a packaging structure according to some other examples of the present disclosure;

FIG. 13D is a top view schematically illustrating another structure at a stage in a manufacturing process of a packaging structure according to some other examples of the present disclosure;

FIG. 14A is a cross-sectional view schematically illustrating a structure at another stage in a manufacturing process of a packaging structure according to some other examples of the present disclosure;

FIG. 14B is a top view schematically illustrating a structure at another stage in a manufacturing process of a packaging structure according to some other examples of the present disclosure;

FIG. 15 is a cross-sectional view schematically illustrating a structure at another stage in a manufacturing process of a packaging structure according to some other examples of the present disclosure;

FIG. 16 is a cross-sectional view schematically illustrating a structure at another stage in a manufacturing process of a packaging structure according to some other examples of the present disclosure; and

FIG. 17 is a cross-sectional view schematically illustrating a structure at another stage in a manufacturing process of a packaging structure according to some other examples of the present disclosure.

It should be understood that the dimensions of the various parts shown in the accompanying drawings are not drawn to actual scale. In addition, the same or similar reference numbers refer to the same or similar components.

### DETAILED DESCRIPTION

Various exemplary examples of the present disclosure will now be described in detail with reference to the accompanying drawings. The description of the exemplary examples is merely illustrative and is in no way intended as any limitation on the disclosure and its applications or uses. The present disclosure may be implemented in many different forms and is not limited to the examples described herein. These examples are provided to enable the disclosure to be thorough and complete, and to fully express the scope of the disclosure to those skilled in the art. It should be noted that, unless specifically stated otherwise, the relative arrangement of components and steps, the composition of materials, numerical expressions, and numerical values set forth in these examples should be interpreted as exemplary only and not as a limitation.

The terms “first,” “second,” and the like used in this disclosure do not represent any order, quantity, or importance, but are merely used to distinguish different parts. A word “comprises” or “comprising” or the like means that an element preceding the word encompasses the elements listed after the word and does not exclude the possibility that other elements are also encompassed. “below”, “above”, “left”, “right” and the like are only used to represent relative position relationships, and when the absolute position of the object to be described changes, the relative position relationship may also change accordingly.

In the present disclosure, when a specific device is described between the first device and the second device, there may be an intervening device between the specific device and the first device or the second device, or intervening devices may not be present. When a particular device is described to connect to other devices, the particular device may be directly connected to the other devices without intervening devices, or may not be directly connected to the other devices with intervening devices. Here, the connections involved in the present disclosure may comprise conductive connections.

All terms used in this disclosure, comprising technical terms or scientific terms, are the same as understood by one of ordinary skill in the art to which this disclosure pertains, unless specifically defined otherwise. It should also be understood that terms such as defined in a generic dictionary should be interpreted as having a meaning that is consistent with their meaning in the context of the related art, without applying an idealized or extremely formalized sense, unless expressly so defined herein.

Techniques, methods, and devices known to one of ordinary skill in the relevant art may not be discussed in detail, but where appropriate, the techniques, methods, and devices should be taken as part of the specification.

The inventors of the present disclosure have found that, for different packaging structures, different packaging substrates used may be designed differently. That is, in the packaging process, the substrate is a substrate with a customized design, which leads to an extension of the design cycle, and also increases the production cost because the mold cannot be shared.

In view of this, examples of the present disclosure provide a packaging structure, so as to shorten the design cycle and reduce the production cost.

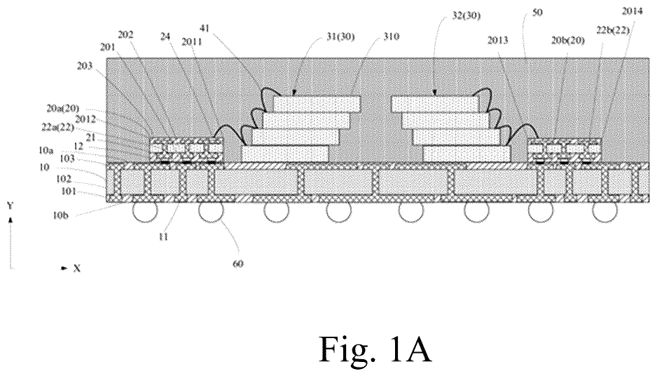

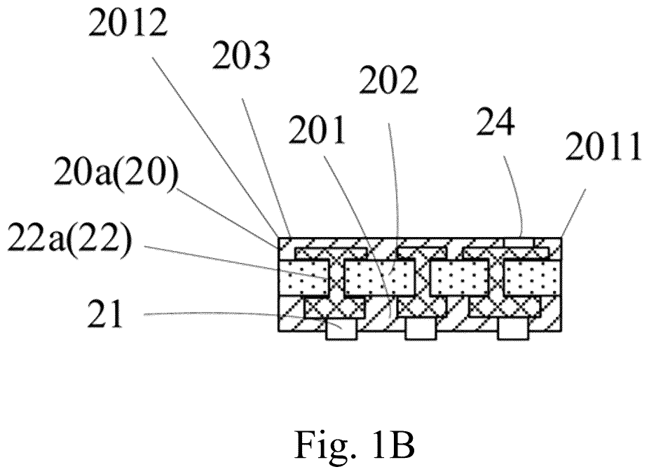

FIG. 1A is a cross-sectional view schematically illustrating a packaging structure according to some examples of the present disclosure. FIG. 1B is an enlarged cross-sectional view schematically illustrating an adapter board according to some examples of the present disclosure.

As shown in FIG. 1A, the packaging structure comprises a substrate 10. The substrate 10 comprises a first wiring layer 11. For example, the substrate 10 may further comprise a first insulating layer 101, a second insulating layer 102, and a third insulating layer 103. The first insulating layer 101, the second insulating layer 102, and the third insulating layer 103 surround the first wiring layer 11. For example, the materials of the first insulating layer 101 and the third insulating layer 103 comprise ink. The first insulation layer and the third insulation layer may function as insulation and protection. For example, the material of the second insulating layer 102 comprises a dielectric material (e.g., resin and/or glass fiber, etc.). As shown in FIG. 1A, the substrate 10 comprises a first surface 10a and a second surface 10b opposite to the first surface 10a. Here, the substrate may be a general design substrate. The general design substrate can be used in different generations of storage products, such as a storage product with an increased number of layers of NAND or a storage product of different control chips, etc.

As shown in FIG. 1A, the packaging structure further comprises one or more adapter boards 20. The one or more adapter boards 20 are located on a first side of the substrate 10. That is, the one or more adapter boards 20 are located on the first surface 10a of the substrate 10. As shown in FIGS. 1A and 1B, each adapter board 20 comprises a second wiring layer 22. The second wiring layer 22 is connected to the first wiring layer 11. The adapter board comprises a first adapter board. For example, two adapter boards 20a and 20b are shown in FIG. 1A, the adapter board 20a may be referred to as a first adapter board, and the adapter board 20b may be referred to as a second adapter board. As shown in FIGS. 1A and 1B, the first adapter board 20a comprises a second wiring layer 22a, and the second adapter board 20b comprises a second wiring layer 22b. FIG. 1B schematically illustrates a first adapter board 20a. For example, the adapter board 20 may comprise a printed circuit board, an interposer, a substrate, or the like. For example, the circuit wiring structure of the substrate used as the adapter board is different from the circuit wiring structure of the general substrate (i.e., the substrate 10), however, the material of the adapter board may be the same as the material of the general substrate. The adapter board may also be a silicon adapter layer or the like. The adapter board can be designed according to product requirements, that is, the adapter board adopts a customized adapter board. The adapter board can be adaptively adjusted according to the characteristics of the actual product, for example, the circuit structure inside the adapter board can be adjusted.

As shown in FIG. 1A, the packaging structure further comprises one or more stacks 30. The one or more stacks 30 are located on a first side of the substrate 10. That is, the one or more stacks 30 are located on the first surface 10a of the substrate 10. Each stack comprises one or more chips 310. Here, in each stack, the plurality of chips 310 are stacked. For example, in each stack, the number of the plurality of chips stacked may be 4,8, 16, etc. In addition, it should be noted that, for a case where the stack comprises only one chip 310, this case may be considered as a special stacking setting manner. Each stack may be stepped. The chip 310 is a memory chip. For example, the chip 310 is a NAND (e.g., a raw NAND (rNAND)) chip or a dynamic random access memory (DRAM) chip. Here, rNAND is a NAND product with NAND chips without other chips (e.g., control chips). Here, the stack comprises a first stack 31 connected to a second wiring layer 22a in the first adapter board 20a.

For example, two stacks 31 and 32 are shown in FIG. 1A, the stack 31 may be referred to as a first stack, and the stack 32 may be referred to as a second stack. One or more chips 310 comprised in the first stack 31 are connected to the second wiring layer 22a in the first adapter board 20a. One or more chips 310 comprised in the second stack 32 are connected to the second wiring layer 22b in the second adapter board 20b.

Here, the arrangement direction of the one or more stacks 30 and the one or more adapter boards 20 is perpendicular to the thickness direction of the substrate 10. As shown in FIG. 1A, the arrangement direction of the stack and the adapter board is the X direction, which is the direction parallel to the first surface 10a of the substrate 10, and the thickness direction of the substrate 10 is the Y direction, which is the direction perpendicular to the first surface 10a of the substrate 10. Here, the arrangement direction of the stack 30 and the adapter board 20 is perpendicular to the thickness direction of the substrate 10. That is, the stack 30 and the adapter board 20 are tiled on the first surface 10a of the substrate. In this way, the thickness of the whole packaging structure can be reduced, which facilitates the light and thin design of the packaging structure.

So far, a packaging structure according to some examples of the present disclosure is provided. The packaging structure comprises: a substrate comprising a first wiring layer; one or more adapter boards located on a first side of the substrate, each adapter board comprising a second wiring layer connected to the first wiring layer, the one or more adapter boards comprising a first adapter board; and one or more stacks located on a first side of the substrate, each stack comprising one or more chips, the one or more stacks comprising a first stack connected to a second wiring layer in the first adapter board, wherein an arrangement direction of the one or more stacks and the one or more adapter boards is perpendicular to a thickness direction of the substrate. In the packaging structure, the stack is electrically connected with the substrate through the adapter board, different adapter boards can be adopted for different products, and the substrate can be a general substrate. Therefore, the packaging structure can shorten the design cycle, the structure process is simple, and the production cost is reduced.

Here, the wiring structure inside the general substrate can meet connection requirements of connection between different generations of storage products and other devices. For example, a metal bump meeting a standard layout requirement may be disposed on the general substrate, so as to be connected to another device. The wiring structure inside the adapter board can meet the connection requirements of the same generation of storage products and the general substrate. For different generations of storage products, different adapter boards may be used. In this way, when the packaging structure is designed, the corresponding adapter board needs to be designed, but the general substrate does not need to be redesigned, so that the design cycle can be shortened, the structure process is simple, and the production cost is reduced.

As described above, as shown in FIG. 1A, the one or more adapter boards comprise a first adapter board 20a and a second adapter board 20b. In some examples, the structure of the second wiring layer 22a in the first adapter board 20a is the same as the structure of the second wiring layer 22b in the second adapter board 20b. Here, the structure of the second wiring layer is a wiring structure of the second wiring layer.

For example, in an rNAND product having a plurality of adapter boards, in the plurality of adapter boards, a wiring structure of a second wiring layer of any two adapter boards is the same.

As previously described, one or more stacks comprise a first stack 31 and a second stack 32, as shown in FIG. 1A. In some examples, the number and type of chips in the first stack 31 is the same as the number and type of chips in the second stack 32. For example, both the number of the chips in the first stack 31 and the number of the chips in the second stack 32 are 4, and both the type of the chips in the first stack 31 and the type of the chips in the second stack 32 are rNAND chips.

The first stack 31 is connected to the second wiring layer 22a in the first adapter board 20a, and the second stack 32 is connected to the second wiring layer 22b in the second adapter board 20b. For example, the plurality of stacks are connected to the plurality of adapter boards in a one-to-one correspondence. In this way, the connection between the plurality of stacks and the plurality of adapter boards can be achieved on the same substrate.

As shown in FIG. 1A, the substrate 10 may further comprise a plurality of first pads 12. The plurality of first pads 12 are located between the first wiring layer 11 and the one or more adapter boards 20. The plurality of first pads 12 are connected to the first wiring layer 11. By disposing the first pad, the connection between the substrate and the adapter board can be facilitated.

As shown in FIG. 1A and FIG. 1B, each adapter board 20 may further comprise a plurality of second pads 21 and a plurality of third pads 24. The plurality of second pads 21 are located between the second wiring layer 22 and the substrate 10. The plurality of second pads 21 are connected to the second wiring layer 22 and connected to the plurality of first pads 12. For example, the plurality of second pads 21 are connected to the plurality of first pads 12 in a one-to-one correspondence. The plurality of third pads 24 are located on a side of the second wiring layer 22 away from the substrate. That is, the second wiring layer 22 is located between the plurality of third pads 24 and the substrate 10. The plurality of third pads 24 are connected to the second wiring layer 22 and the one or more stacks 30. Here, by disposing the second pad, the connection between the adapter board and the substrate can be facilitated, and by disposing the third pad, the connection between the adapter board and the stack can be facilitated.

In some examples, the shapes of the first pad 12, the second pad 21, and the third pad 24 may be circular, elliptical, square, or other shapes, respectively. It should be noted that the scope of the present disclosure is not limited to the specific shapes of the pads.

As shown in FIGS. 1A and 1B, the third pad 24 in the first adapter board 20a is connected to the first stack 31, and the third pad 24 in the second adapter board 20b is connected to the second stack 32. The first stack 31 and the second stack 32 are located between the first adapter 20a and the second adapter 20b. In a direction (i.e., the X direction) parallel to the first surface 10a of the substrate 10, the first end (e.g., the right end) 2011 of the first adapter board 20a is closer to the first stack 31 than the second end (e.g., the left end) 2012 of the first adapter board 20a, and in this case, the plurality of third pads 24 in the first adapter board 20a are closer to the first end 2011 of the first adapter board 20a than the second end 2012 of the first adapter board 20a. In a direction (i.e., the X direction) parallel to the first surface 10a of the substrate 10, the first end (e.g., the left end) 2013 of the second adapter board 20b is closer to the second stack 32 than the second end (e.g., the right end) 2014 of the second adapter board 20b, and in this case, the plurality of third pads 24 in the second adapter board 20b are closer to the first end 2013 of the second adapter board 20b than the second end 2014 of the second adapter board 20b. By designing the position of the third pad on each adapter board in this way, the connection between the adapter board and the stack can be facilitated.

As shown in FIG. 1A and FIG. 1B, the adapter board 20 may further comprise a fourth insulating layer 201, a fifth insulating layer 202, and a sixth insulating layer 203. The fourth insulating layer 201, the fifth insulating layer 202, and the sixth insulating layer 203 surround the second wiring layer 22. For example, the materials of the fourth insulating layer 201 and the sixth insulating layer 203 comprises ink. The fourth insulation layer and the sixth insulation layer may function as insulation and protection. The material of the fifth insulating layer 202 comprises a dielectric material (e.g., resin and/or glass fiber, etc.).

As shown in FIG. 1A, the packaging structure may further comprise a first lead 41. The first lead 41 is connected to the plurality of third pads 24 of the adapter board and the one or more stacks 30. That is, the stack is connected to the adapter board through the first lead 41. In this example, one or more chips 310 in the stack are connected to the corresponding adapter board through the first leads 41, and the adapter board is connected to the substrate, so that electrical connection between the stack and the substrate is achieved.

In some examples, the material of the first lead 41 comprises a metal such as gold. It should be noted that the scope of the present disclosure is not limited to the specific material of the first lead.

As shown in FIG. 1A, the packaging structure further comprises an encapsulation layer 50. The encapsulation layer 50 covers one or more adapter boards 20 and one or more stacks 30. The encapsulation layer 50 is disposed on the first surface 10a of the substrate 10. For example, the material of the encapsulation layer comprises an epoxy molding compound or the like. Sealing of the adapter board and the stack can be achieved by the encapsulation layer.

As shown in FIG. 1A, the packaging structure further comprises a plurality of metal bumps 60. The plurality of metal bumps 60 are located on the second side of the substrate 10. Here, the second side of the substrate 10 is opposite to the first side of the substrate 10. In other words, the plurality of metal bumps 60 are located on the second surface 10b of the substrate 10. In addition, the plurality of metal bumps 60 are connected to the first wiring layer 11. For example, the metal bump comprises a solder ball. Through the metal bumps, the packaging structure may be connected to other devices.

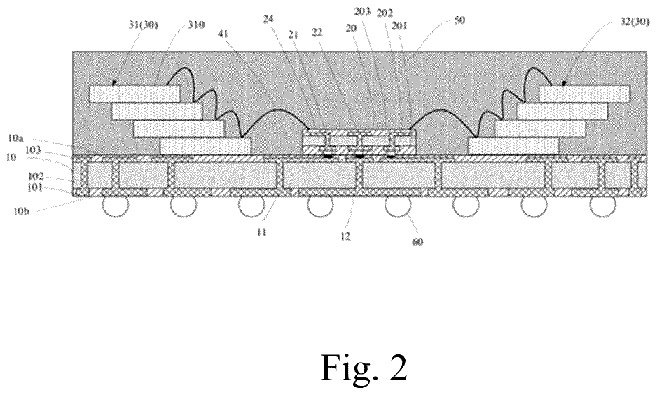

FIG. 2 is a cross-sectional view schematically illustrating a packaging structure according to some other examples of the present disclosure.

Compared with the packaging structure shown in FIG. 1A, the packaging structure shown in FIG. 2 differs in that a plurality of stacks may be connected to the same adapter board. For example, the packaging structure as shown in FIG. 2 may be applied to a product such as rNAND.

As shown in FIG. 2, the packaging structure comprises a substrate 10, one or more adapter boards 20, and one or more stacks 30. The one or more adapter boards 20 comprise a first adapter board 20, and the first adapter board 20 comprises a second wiring layer 22. The one or more stacks 30 comprise a first stack 31 and a second stack 32. The first stack 31 is connected to the second wiring layer 22 in the first adapter board 20, and the second stack 32 is also connected to the second wiring layer 22 in the first adapter board 20. The number and type of chips in the first stack 31 is the same as the number and type of chips in the second stack 32. By connecting the plurality of stacks to the same adapter board, sharing of the plurality of stacks on the adapter board is realized, the number of the adapter boards can be reduced, and the production cost is reduced.

It can be seen from the above description that the number of the adapter boards can be set according to actual needs. For example, for the packaging structure shown in FIG. 1A, at least two adapter boards may be disposed (for example, the number of the adapter boards and the number of the stacks are same). For another example, for the packaging structure shown in FIG. 2, an adapter board may be disposed, and the plurality of stacks share the adapter board.

Similar to the packaging structure shown in FIG. 1A, in the packaging structure shown in FIG. 2, the substrate 10 may comprise a plurality of first pads 12, and the first adapter board 20 may comprise a plurality of second pads 21 and a plurality of third pads 24. The plurality of second pads 21 are connected to the second wiring layer 22 and connected to the plurality of first pads 12. The plurality of third pads 24 are connected to the second wiring layer 22 and the plurality of stacks 30.

As shown in FIG. 2, a first portion of the plurality of third pads 24 in the first adapter board 20 is connected to the first stack 31, and a second portion of the plurality of third pads 24 in the first adapter board 20 is connected to the second stack 32. The first portion of pads are closer to the first stack 31 than the second portion of pads. The second portion of pads are closer to the second stack 32 than the first portion of pads. By setting the position of the third in this way, a plurality of stacks can be conveniently connected to the same pad.

In addition, the packaging structure shown in FIG. 2 has the same or similar components as the packaging structure shown in FIG. 1A, and these components may be referred to the description of the same or similar components in the packaging structure shown in FIG. 1A, and details are not described herein again.

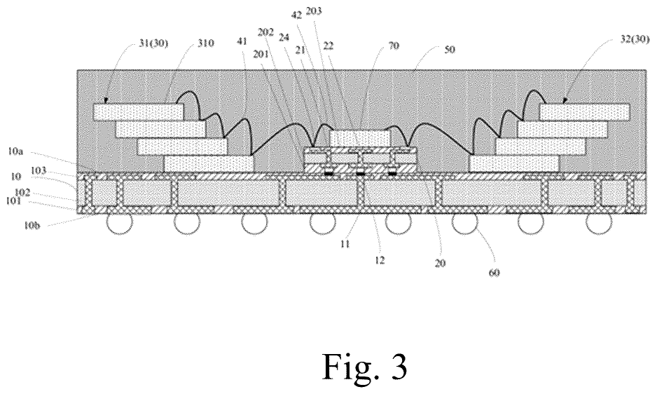

FIG. 3 is a cross-sectional view schematically illustrating a packaging structure according to some other examples of the present disclosure.

As shown in FIG. 3, the packaging structure comprises a substrate 10. The substrate 10 comprises a first wiring layer 11. Similar to the foregoing description, the substrate 10 may further comprise a first insulating layer 101, a second insulating layer 102, and a third insulating layer 103 surrounding the first wiring layer 11. As shown in FIG. 3, the substrate 10 comprises a first surface 10a and a second surface 10b opposite to the first surface 10a. Here, the substrate may be a general design substrate.

As shown in FIG. 3, the packaging structure further comprises one or more adapter boards 20. The one or more adapter boards 20 are located on a first side of the substrate 10. That is, the one or more adapter boards 20 are located on the first surface 10a of the substrate 10. The one or more adapter boards 20 are located on the first surface 10a of the substrate 10. Each adapter board comprises a second wiring layer 22. The second wiring layer 22 is connected to the first wiring layer 11. The adapter board comprises a first adapter board 20. For example, the adapter board 20 may comprise a printed circuit board, an interposer, or a substrate. For example, the circuit wiring structure of the substrate used as the adapter board is different from the circuit wiring structure of the general substrate (i.e., the substrate 10). However, the material of the adapter board may be the same as the material of the general substrate. The adapter board can be designed according to product requirements, that is, the adapter board adopts a customized adapter board.

As shown in FIG. 3, the packaging structure further comprises one or more stacks 30. The one or more stacks 30 are located on a first side of the substrate 10. The one or more stacks 30 are located on the first surface 10a of the substrate 10. Each stack comprises one or more first chips 310. For example, in each stack, the number of the plurality of first chips stacked may be 4,8, 16, etc. Here, the first chip 310 is a memory chip. For example, the first chip is a NAND (e.g., a manage NAND (mNAND)) chip or a DRAM chip, etc. Here, mNAND is a NAND product having a NAND chip and a control chip. The one or more stacks comprise a first stack 31. The first stack 31 is connected to the second wiring layer 22 in the first adapter board 20. Similar to the foregoing description, the arrangement direction of the one or more stacks 30 and the one or more adapter board is perpendicular to the thickness direction of the substrate 10.

As shown in FIG. 3, the packaging structure further comprises a second chip 70. The second chip 70 is connected to the second wiring layer 22 in the first adapter board 20. The second chip 70 is located on a side of the first adapter board 20 away from the substrate 10. That is, the first adapter board 20 is located between the second chip 70 and the substrate 10. Here, the second chip is a control chip.

So far, a packaging structure according to some other examples of the present disclosure is provided. The packaging structure comprises: a substrate comprising a first wiring layer; one or more adapter boards located on a first side of the substrate, each adapter board comprising a second wiring layer connected to the first wiring layer, the one or more adapter boards comprising a first adapter board; one or more stacks located on a first side of the substrate, each stack comprising one or more first chips, the one or more stacks comprising a first stack connected to a second wiring layer in the first adapter board, wherein an arrangement direction of the one or more stacks and the one or more adapter boards is perpendicular to a thickness direction of the substrate; and a second chip connected to a second wiring layer in the first adapter board, wherein the first adapter board is located between the second chip and the substrate. In the packaging structure, the stack is electrically connected with the substrate through the adapter board, different adapter boards can be adopted for different products, and the substrate can adopt a general substrate, so that the packaging structure can shorten the design cycle, the structure process is simple, and the production cost is reduced. Moreover, the packaging structure is further integrated with a second chip, which further improves the integration level of the packaging structure.

As shown in FIG. 3, the one or more stacks 30 may further comprise a second stack 32. The second stack 32 is connected to the second wiring layer 22 in the first adapter board 20. That is, in the packaging structure shown in FIG. 3, both the first stack 31 and the second stack 32 are connected to the second wiring layer 22 in the first adapter board 20. That is, a plurality of stacks may be connected to the same adapter board. The number of the adapter boards can be reduced, and the production cost can be reduced.

In some examples, the number and type of chips in the first stack 31 is the same as the number and type of chips in the second stack 32. For example, both the number of the chips in the first stack 31 and the number of the chips in the second stack 32 are 4, and both the type of the chips in the first stack 31 and the type of the chips in the second stack 32 are mNAND chips. In this case, the plurality of stacks may share a same adapter board and a same second chip. This can reduce the number of the adapter board and the second chip and reduce the production cost.

In other examples, the one or more adapter boards may comprise a first adapter board, and may further comprise a second adapter board, the one or more stacks may comprise a first stack and a second stack, wherein the first stack is connected to the second wiring layer in the first adapter board, the second stack is connected to the second wiring layer in the second adapter board, and the second chip located on the first adapter board is connected to the second wiring layer in the first adapter board, and is not connected to the second wiring layer in the second adapter board.

In this case, the structure (i.e., the wiring structure) of the second wiring layer in the first adapter board is different from the structure of the second wiring layer in the second adapter board, and the number or type of the first chips in the first stack is different from the number or type of the first chips in the second stack. Thus, the stack and the adapter board may be disposed such that different stacks are connected to different adapter boards. That is, in the packaging structure, a plurality of stacks may be connected to different adapter boards.

Returning to FIG. 3, the substrate 10 may further comprise a plurality of first pads 12 located between the first wiring layer 11 and the one or more adapter board boards 20 and connected to the first wiring layer 11.

As shown in FIG. 3, each adapter board 20 may further comprise a plurality of second pads 21 and a plurality of third pads 24. The plurality of second pads 21 are located between the second wiring layer 22 and the substrate 10. The plurality of second pads 21 are connected to the second wiring layer 22 and connected to the plurality of first pads 12. The plurality of third pads 24 are located on a side of the second wiring layer 22 away from the substrate 10. That is, the second wiring layer 22 is located between the plurality of third pads 24 and the substrate 10. The plurality of third pads 24 are connected to the second wiring layer 22 and the one or more stacks 30. For example, the plurality of third pads 24 are connected to the first stack 31 and the second stack 32.

As shown in FIG. 3, the first stack 31 is connected to a first portion of the plurality of third pads 24 in the first adapter board 20, and the second stack 32 is connected to a second portion of the plurality of third pads 24 in the first adapter board 20. The first portion of pads are closer to the first stack 31 than the second partial pad, and the second portion of pads are closer to the second stack 32 than the first portion of pads. Therefore, the plurality of stacks are connected to the same adapter board, the number of the adapter boards is reduced, and the production cost is reduced.

In some other examples, the one or more stacks comprise a first stack and a second stack, the one or more adaptor boards comprise a first adaptor board and a second adaptor board, wherein a second chip located on the first adaptor board is connected to a second wiring layer in the first adaptor board and not to a second wiring layer in the second adaptor board, a plurality of third pads in the first adaptor board are connected to the first stack, and a plurality of third pads in the second adaptor board are connected to the second stack. Similar to the packaging structure shown in FIG. 1A, in a direction (that is, the X direction) parallel to the first surface of the substrate, the first end (e.g., the right end, similar to the first end 2011 in FIG. 1A) of the first adapter board is closer to the first stack than the second end (e.g., the left end, similar to the second end 2012 in FIG. 1A) of the first adapter board, and in this case, the plurality of third pads in the first adapter board are closer to the first end of the first adapter board than the second end of the first adapter board; and in a direction (that is, the X direction) parallel to the first surface of the substrate, the first end (e.g., the left end, similar to the first end 2013 in FIG. 1A) of the second adapter board is closer to the second stack than the second end (e.g., the right end, similar to the second end 2014 in FIG. 1A) of the second adapter board, and in this case, the plurality of third pads in the second adapter board are closer to the first end of the second adapter board than the second end of the second adapter board.

Referring back to FIG. 3, similar to the packaging structure shown in FIG. 1A, in the packaging structure shown in FIG. 3, the adapter board 20 may further comprise a fourth insulating layer 201, a fifth insulating layer 202, and a sixth insulating layer 203. The fourth insulating layer 201, the fifth insulating layer 202, and the sixth insulating layer 203 surround the second wiring layer 22.

As shown in FIG. 3, the packaging structure may further comprise a first lead 41. The first lead 41 is connected to a plurality of third pads 24 and one or more stacks 30. That is, the stack 30 is connected to the plurality of third pads 24 of the first adapter board through the first lead 41. In this way, electrical connection between the stack and the adapter board is achieved.

As shown in FIG. 3, the packaging structure may further comprise a second lead 42. The second lead 42 is connected to the second chip 70 and the second wiring layer 22 in the first adapter board 20. That is, the second chip 70 is connected to the second wiring layer 22 in the first adapter board 20 through the second lead 42. In this way, electrical connection between the second chip and the adapter board is achieved.

In some examples, the material of the second lead 42 comprises a metal such as gold. It should be noted that the scope of the present disclosure is not limited to the specific material of the first lead.

As shown in FIG. 3, the packaging structure may further comprise an encapsulation layer 50. The encapsulation layer 50 covers one or more adapter boards 20, one or more stacks 30, and a second chip 70. The encapsulation layer 50 is located on the first surface 10a of the substrate 10.

As shown in FIG. 3, the packaging structure may further comprise a plurality of metal bumps 60. The plurality of metal bumps 60 are located on the second side of the substrate. The second side is opposite the first side. That is, the plurality of metal bumps 60 are located on the second surface 10b of the substrate. The plurality of metal bumps 60 are connected to the first wiring layer 11.

In addition, it should be noted that the packaging structure shown in FIG. 3 further comprises other components that are the same as or similar to those shown in FIG. 1A or FIG. 2, these components will not be described in detail again, and reference may be made to the description of the components of the packaging structure shown in FIG. 1A or FIG. 2.

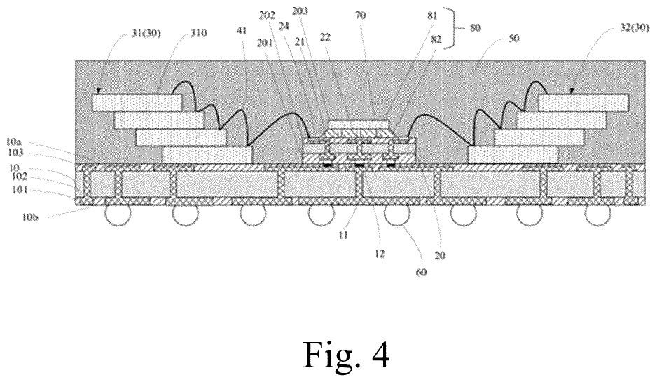

FIG. 4 is a cross-sectional view schematically illustrating a packaging structure according to some other examples of the present disclosure.

Compared with the packaging structure shown in FIG. 3, the packaging structure shown in FIG. 4 differs from that in the packaging structure shown in FIG. 4, the second chip is connected to the first adapter board through a flip-chip structure.

As shown in FIG. 4, the packaging structure comprises a flip-chip structure 80. The flip-chip structure 80 is located between the second chip 70 and the first adapter board 20, and is connected to the second chip 70 and the second wiring layer 22 in the first adapter board 20.

For example, as shown in FIG. 4, the flip-chip structure 80 comprises a fourth pad 81 and a filler layer 82. The fourth pad 81 is located between the second chip 70 and the second wiring layer 22 in the first adapter board 20. The fourth pad 81 is connected to the second chip 70 and the second wiring layer 22, thereby realizing electrical connection between the second chip and the second wiring layer. The filler layer 82 is filled around the fourth pad 81. That is, the filler layer 82 surrounds the fourth pad 81. The filler layer 82 may be made of an insulating material such as epoxy resin, and may function as insulation and support.

In the above example, the second chip is connected to the first adapter board by a flip-chip structure, thereby providing another implementation by which the second chip is connected to the first adapter board.

It should be noted that the packaging structure shown in FIG. 4 further comprises other components that are the same as or similar to the packaging structure shown in FIG. 3, and these components will not be described in detail again, and reference may be made to the description of the components of the packaging structure shown in FIG. 3.

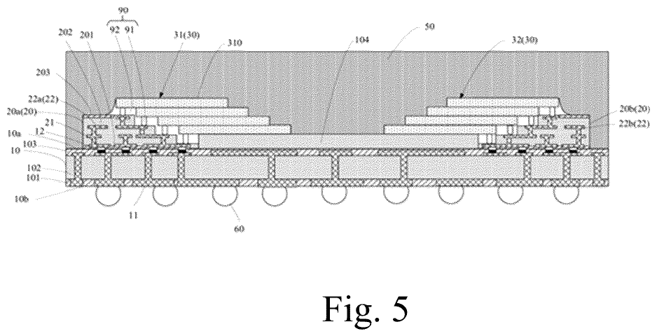

FIG. 5 is a cross-sectional view schematically illustrating a packaging structure according to some other examples of the present disclosure.

As shown in FIG. 5, the packaging structure comprises a substrate 10. The substrate 10 comprises a first wiring layer 11. Similar to the foregoing description, the substrate 10 may further comprise a first insulating layer 101, a second insulating layer 102, and a third insulating layer 103 surrounding the first wiring layer 11. As shown in FIG. 3, the substrate 10 comprises a first surface 10a and a second surface 10b opposite to the first surface 10a. Here, the substrate may be a general design substrate.

In some examples, as shown in FIG. 5, the substrate 10 may further comprise a support portion 104 located on a first side of the first wiring layer 11.

As shown in FIG. 5, the packaging structure further comprises one or more adapter boards 20. The one or more adapter boards 20 are located on a first side of the substrate 10. That is, the one or more adapter boards 20 are located on the first surface 10a of the substrate 10. The adapter board 20 is stepped. Each adapter board 20 comprises a second wiring layer 22. The second wiring layer 22 is connected to the first wiring layer 11. The adapter board comprises a first adapter board. For example, two adapter boards 20a and 20b are shown in FIG. 5, the adapter board 20a may be referred to as a first adapter board, and the adapter board 20b may be referred to as a second adapter board. As shown in FIG. 5, the first adapter board 20a comprises a second wiring layer 22a, and the second adapter board 20b comprises a second wiring layer 22b. For example, the adapter board 20 may comprise another substrate or the like. The adapter board can be designed according to product requirements, that is, the adapter board adopts a customized adapter board.

As shown in FIG. 5, the adapter board 20 may further comprise a fourth insulating layer 201, a fifth insulating layer 202, and a sixth insulating layer 203. The fourth insulating layer 201, the fifth insulating layer 202, and the sixth insulating layer 203 surround the second wiring layer 22.

As shown in FIG. 5, the packaging structure further comprises one or more stacks 30. The one or more stacks 30 are located on a first side of the substrate 10. For example, the one or more stacks 30 are located on the support portion 104 of the substrate 10. Each stack 30 comprises one or more chips 310. Here, in each stack, the plurality of chips 310 are stacked. For example, in each stack, the number of the plurality of chips stacked may be 4,8, 16, etc. In addition, it should be noted that, for a case where the stack comprises only one chip 310, this case may be considered as a special stacking setting manner. The chip 310 is a memory chip. For example, the chip is a NAND (e.g., rNAND) chip or a DRAM chip. The stack comprises a first stack 31 connected to a second wiring layer in the first adapter board.

For example, two stacks 31 and 32 are shown in FIG. 5, the stack 31 may be referred to as a first stack, and the stack 32 may be referred to as a second stack. For example, the number and type of chips in the first stack 31 is the same as the number and type of chips in the second stack 32. One or more chips 310 comprised in the first stack 31 are connected to the second wiring layer 22a in the first adapter board 20a. One or more chips 310 comprised in the second stack 32 are connected to the second wiring layer 22b in the second adapter board 20b.

So far, a packaging structure according to some other examples of the present disclosure is provided. In the packaging structure, the stack is electrically connected with the substrate through the adapter board, different adapter boards can be adopted for different products, and the substrate can be a general substrate. Therefore, the packaging structure can shorten the design cycle, the structure process is simple, and the production cost is reduced.

In the related art, the inventor of the present disclosure also finds that in the multi-chip packaging design, the arc height of the bonding wires can occupy more vertical direction space, light and thin are not easy to realize, and the product competitiveness is reduced. Moreover, for such multi-chip packaging design, the thickness of the chip needs to be thin due to the requirement of limiting the total thickness of the packaging, and when the thickness of the chip is thin, the product yield and the product performance are reduced.

Through the adoption of the packaging structure provided by the example of the present disclosure, since the lead in the packaging structure are omitted, the thickness of the whole packaging structure can be reduced. In this way, the thickness requirement of the packaging structure can be met even if the thickness of each chip is increased. Therefore, in the packaging structure of the examples of the present disclosure, the thickness of each chip may be increased, which may improve product yield and product performance.

As shown in FIG. 5, the packaging structure comprises a connection structure 90, and the connection structure 90 is connected between the stack 30 and the adapter board 20. For example, the connection structure 90 comprises a connector 91 between the stack 30 and the adapter board 20, and a filler layer (which may be referred to as a first filler layer) 92 filled around the connector 91. The material of the connector comprises a metal material, and the material of the filler layer 92 comprises an insulating material such as epoxy resin. The connector may realize electrical connection between the stack and the adapter board, and the filler layer may function as insulation and support.

In addition, similar to the foregoing description, the substrate 10 may further comprise a plurality of first pads 12, the adapter board 20 may further comprise a plurality of second pads 21, the packaging structure further comprises an encapsulation layer 50 and a plurality of metal bumps 60, the first pads 12, the second pads 21, the encapsulation layer 50, and the metal bumps 60 may be referred to the foregoing description, and details are not described herein again.

Here, it should be noted that, in the packaging structure shown in FIG. 5, since the leads in the encapsulation structure are omitted, the mold cap clearance of the encapsulation layer may be increased (for example, the mold cap clearance here may be understood as the distance from the upper surface of the encapsulation layer to the upper surface of other portions of the encapsulation structure (for example, the stack)), thereby improving the mechanical performance of the 3PB (Three-Point Bending) of the product.

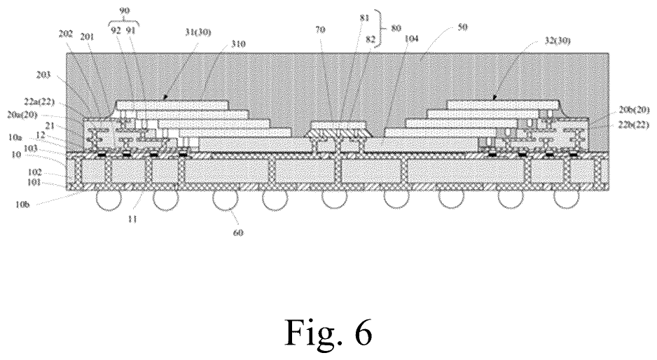

FIG. 6 is a cross-sectional view schematically illustrating a packaging structure according to some other examples of the present disclosure.

Compared with the packaging structure shown in FIG. 5, the packaging structure shown in FIG. 6 differs in that in addition to the substrate 10, the adapter board 20, the stack 30, the encapsulation layer 50, and the metal bumps 60, the packaging structure shown in FIG. 6 further comprises a second chip 70 located on the first side of the substrate 10. For example, the second chip is located above the support portion 104 of the substrate 10. The second chip 70 is connected to the first wiring layer 11 in the substrate 10. Here, the second chip is a control chip.

In addition, as shown in FIG. 6, the packaging structure may further comprise a flip-chip structure 80. The flip-chip structure 80 is located between the second chip 70 and the support portion 104 of the substrate 10. For example, as shown in FIG. 6, the flip-chip structure 80 comprises a fourth pad 81 and a filler layer (which may be referred to as a second filler layer) 82. The fourth pad 81 is located between the second chip 70 and the support portion 104 and is connected to the second chip and the first wiring layer 11. In this way, the connection between the second chip and the first wiring layer is realized. The filler layer 82 is filled around the fourth pad 81. That is, the filler layer 82 surrounds the fourth pad 81. The filler layer 82 may be made of an insulating material such as epoxy resin, which may function as insulation and support.

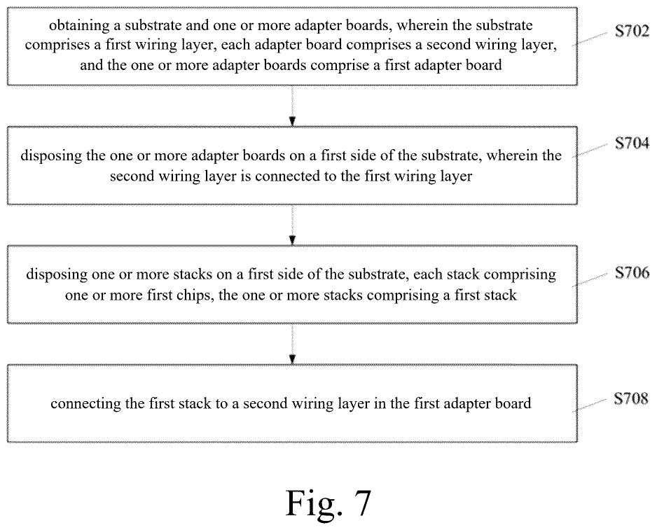

FIG. 7 is a flowchart illustrating a manufacturing method for a packaging structure according to some examples of the present disclosure. As shown in FIG. 7, the manufacturing method comprises steps S702 to S708.

In step S702, a substrate and one or more adapter boards are obtained, wherein the substrate comprises a first wiring layer, each adapter board comprises a second wiring layer, and the one or more adapter boards comprise a first adapter board.

At step S704, one or more adapter boards are disposed on a first side of the substrate, wherein the second wiring layer is connected to the first wiring layer.

At step S706, one or more stacks are disposed on a first side of a substrate, each stack comprising one or more first chips, the one or more stacks comprising a first stack. An arrangement direction of the one or more stacks and the one or more adapter boards is perpendicular to a thickness direction of the substrate.

At step S708, the first stack is connected to a second wiring layer in the first adapter board.

So far, a manufacturing method for a packaging structure according to some examples of the present disclosure is provided. In the manufacturing method, the stack is electrically connected with the substrate through the adapter board, different adapter boards can be adopted for different products, and the substrate can adopt a general substrate, so that the packaging structure formed by the manufacturing method can shorten the design cycle and reduce the production cost.

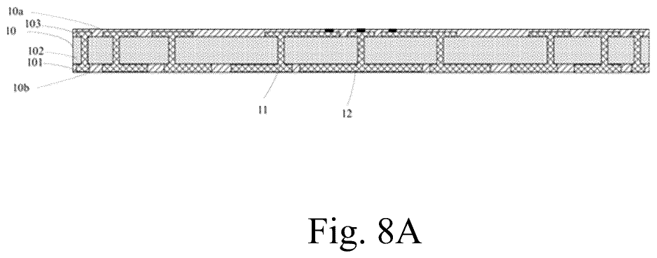

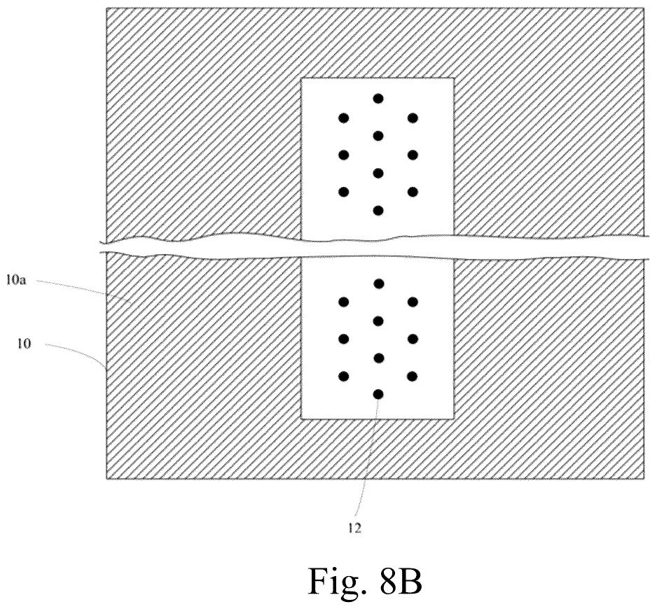

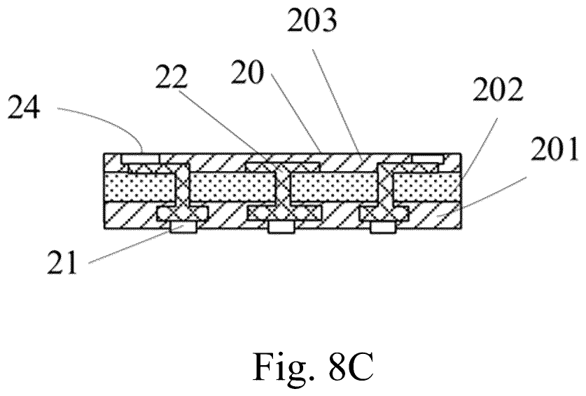

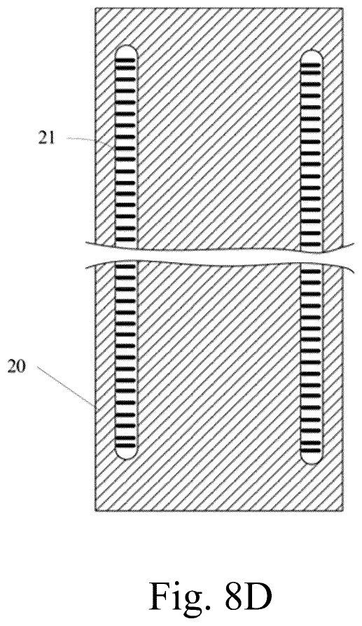

FIG. 8A to FIG. 12 are schematic diagrams schematically illustrating structures at a plurality of stages in a manufacturing process of a packaging structure according to some examples of the present disclosure. The manufacturing method of the packaging structure according to some examples of the present disclosure will be described in detail below with reference to FIG. 8A to FIG. 12 and FIG. 2.

As shown in FIGS. 8A and 8B, a substrate 10 is obtained. For example, the substrate 10 shown in FIGS. 8A and 8B may be formed by processes such as deposition, coating, photolithography, and etching. The substrate 10 comprises a first wiring layer 11. The substrate 10 further comprises a first insulating layer 101, a second insulating layer 102, and a third insulating layer 103. The first insulating layer 101, the second insulating layer 102, and the third insulating layer 103 surround the first wiring layer 11. The substrate 10 further comprises a plurality of first pads 12. The plurality of first pads 12 are connected to the first wiring layer 11.

As shown in FIGS. 8C and 8D, the adapter board 20 is obtained. For example, the adapter board 20 shown in FIGS. 8C and 8D may be formed by processes such as deposition, coating, photolithography, and etching. The adapter board 20 comprises a second wiring layer 22. The adapter board 20 further comprises a fourth insulating layer 201, a fifth insulating layer 202, and a sixth insulating layer 203. The fourth insulating layer 201, the fifth insulating layer 202, and the sixth insulating layer 203 surround the second wiring layer 22. The adapter board 20 further comprises a plurality of second pads 21 and a plurality of third pads 24. The plurality of second pads 21 and the third pad 24 are both connected to the second wiring layer 22.

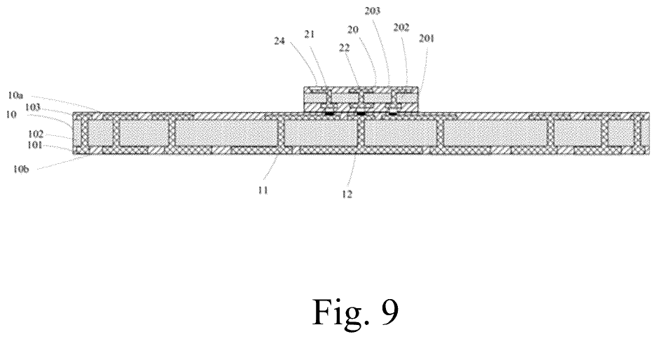

Next, as shown in FIG. 9, the adapter board 20 is disposed on the first side of the substrate 10. That is, the adapter board 20 is disposed on the first surface 10a of the substrate 10. The second wiring layer 22 is connected to the first wiring layer 11. For example, the first pad 12 of the substrate 10 and the second pad 21 of the adapter board 20 are correspondingly connected by a soldering process, so that the second wiring layer 22 is connected to the first wiring layer 11.

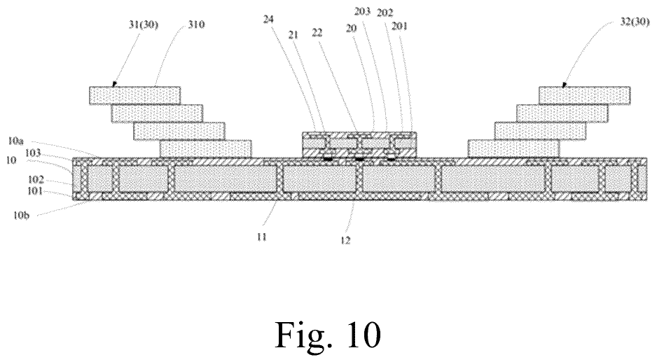

Next, as shown in FIG. 10, one or more stacks 30 are disposed on a first side of the substrate 10, and each stack comprises one or more first chips 310. For example, as shown in FIG. 10, the one or more stacks 30 comprise a first stack 31 and a second stack 32. The arrangement direction of the stack 30 and the adapter board 20 is perpendicular to the thickness direction of the substrate 10.

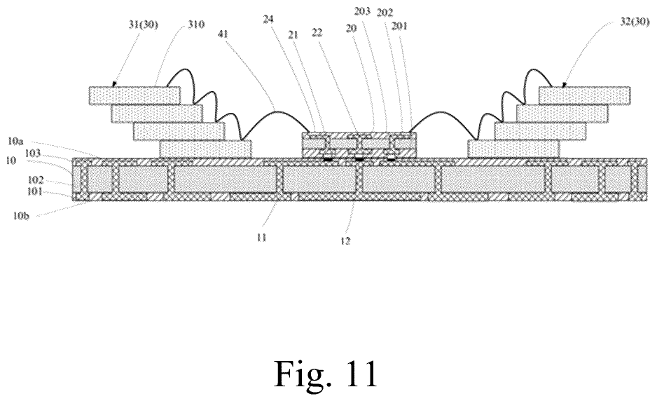

Next, as shown in FIG. 11, for example, by using the first lead 41, the first stack 31 is connected to the second wiring layer 22 in the first adapter board 20 by a wire bonding process. For another example, by using another first lead 41, the second stack 32 may also be connected to the second wiring layer 22 in the first adapter 20 by a wire bonding process. For example, the wire bonding process may comprise: forming a gold ball, forming a first solder joint, forming a wire arc, forming a second solder joint, and breaking a metal wire, or the like. Implementations by which a plurality of stacks are connected to the same adapter board are described herein.

In other examples, different stacks may be connected to different adapter boards. For example, the first stack may be connected to the first adapter board by using one first lead, and the second stack may be connected to the second adapter board by using another first lead.

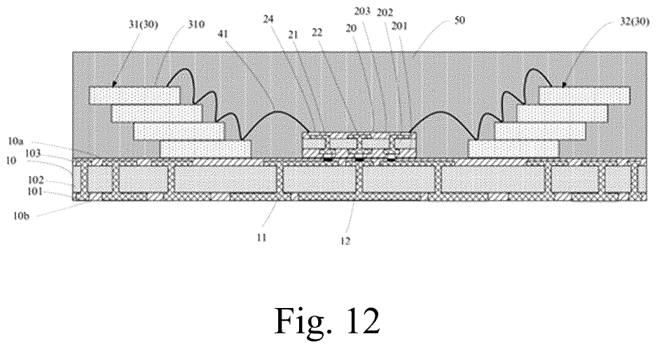

Next, a package layer covering the adapter board and the stack is formed. For example, as shown in FIG. 12, an encapsulation layer 50 covering the adapter board 20, the first stack 31, and the second stack 32 is formed. For example, the material of the encapsulation layer 50 comprises an epoxy molding compound or the like. For example, the epoxy molding compound may be extruded into the mold cavity and the epoxy molding compound may embed the structure shown in FIG. 11 in the mold cavity, and then the epoxy molding compound may be cured to form a structure as shown in FIG. 12.

Next, as shown in FIG. 2, a plurality of metal bumps 60 are disposed on the second side of the substrate 10. The second side is opposite the first side. The plurality of metal bumps 60 are connected to the first wiring layer 11. For example, a plurality of metal bumps 60 are formed on the second surface 10b of the substrate 10 by a ball planting process.

So far, a manufacturing method for a packaging structure according to some examples of the present disclosure is provided. In the manufacturing method, a part of the module of the substrate in the related technology is modified into a substrate serving as a general part, and when a new product has other actual requirements, the adapter board serving as a non-general part can be modified only according to the actual requirement of the new product, and the substrate serving as the general part and the adapter board serving as the non-general part are welded together during production, so that the packaging production is completed. Through the manufacturing method, a packaging structure can be formed. The manufacturing method can shorten the design cycle and reduce the production cost.

In some examples, the manufacturing method may further comprise: disposing a second chip on a side of the first adapter board away from the substrate, and connecting the second chip to the second wiring layer of the first adapter board. For example, on the basis of the structure shown in FIG. 9, in addition to disposing the one or more stacks 30 on the first side of the substrate 10, the second chip 70 may be disposed on a side of the first adapter board 20 away from the substrate 10, that is, the second chip 70 is disposed on the first adapter board 20. For example, the second chip 70 may be connected to the second wiring layer 22 of the first adapter board 20 by using a second lead (such as the second lead 42 shown in FIG. 3) or a flip-chip structure (such as the flip-chip structure 80 shown in FIG. 4). In this way, after other subsequent process steps, a packaging structure as shown in FIG. 3 or a packaging structure as shown in FIG. 4 may be formed.

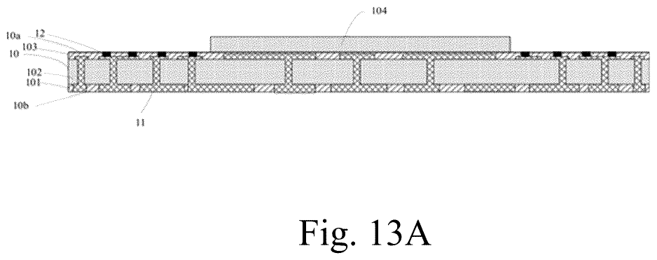

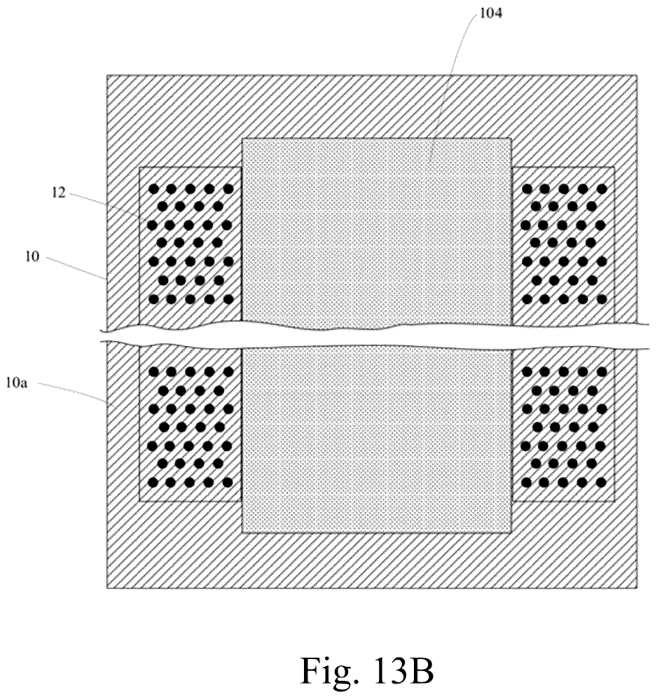

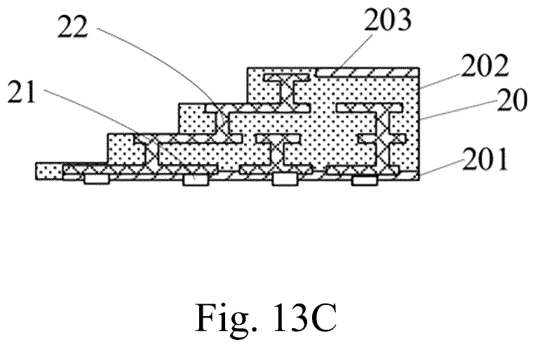

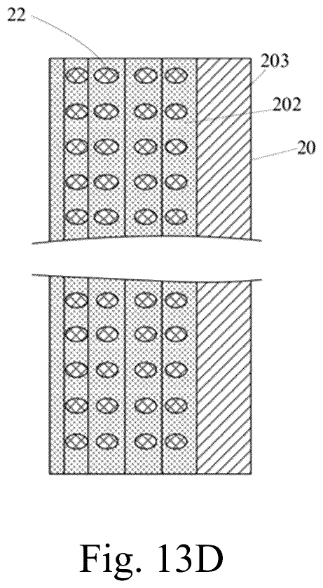

FIG. 13 to FIG. 17 are schematic diagrams schematically illustrating structures at a plurality of stages in a manufacturing process of a packaging structure according to some other examples of the present disclosure. The manufacturing method of the packaging structure according to some other examples of the present disclosure will be described in detail below with reference to FIG. 13A to FIG. 17 and FIG. 5.

As shown in FIG. 13A and FIG. 13B, a substrate 10 is obtained. For example, the substrate 10 shown in FIG. 13A and FIG. 13B may be formed by processes such as deposition, coating, photolithography, and etching. The substrate 10 comprises a first wiring layer 11. The substrate 10 further comprises a first insulating layer 101, a second insulating layer 102, and a third insulating layer 103. The first insulating layer 101, the second insulating layer 102, and the third insulating layer 103 surround the first wiring layer 11. The substrate 10 further comprises a plurality of first pads 12. The plurality of first pads 12 are connected to the first wiring layer 11. The substrate 10 may further comprise a support portion 104 located on a first side of the first wiring layer 11.

As shown in FIGS. 13C and 13D, one or more adapter boards 20 are obtained. For example, the adapter board 20 shown in FIG. 13C and FIG. 13D may be formed by processes such as deposition, coating, photolithography, and etching. The adapter board 20 comprises a second wiring layer 22. The adapter board 20 further comprises a fourth insulating layer 201, a fifth insulating layer 202, and a sixth insulating layer 203. The fourth insulating layer 201, the fifth insulating layer 202, and the sixth insulating layer 203 surround the second wiring layer 22. The adapter board 20 is stepped. At the step, the adapter board may expose a portion of the structure of the second wiring layer 22. The adapter board 20 further comprises a plurality of second pads 21. The plurality of second pads 21 are connected to the second wiring layer 22.

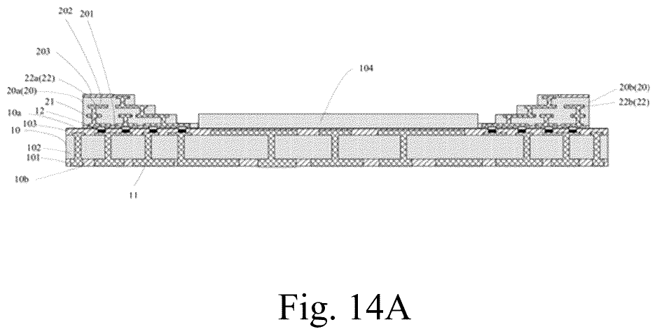

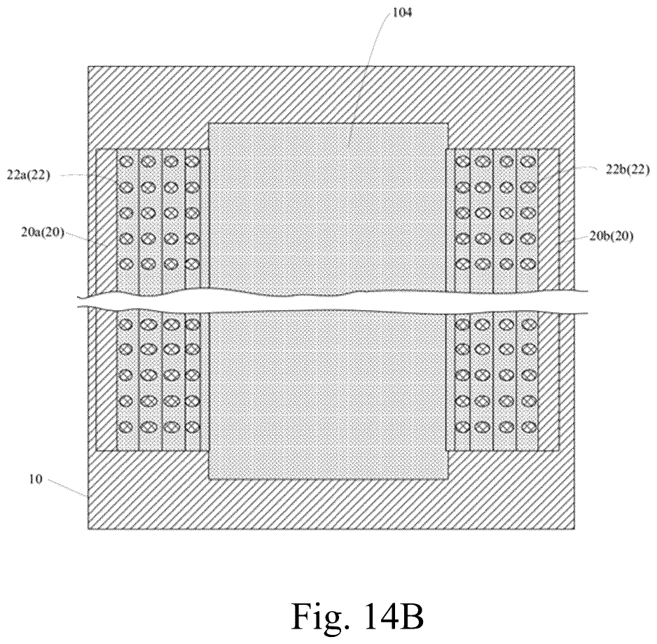

Next, as shown in FIGS. 14A and 14B, one or more adapter boards 20 are disposed on the first side of the substrate 10. That is, the adapter board 20 is disposed on the first surface 10a of the substrate 10. For example, the one or more adapter boards 20 comprise a first adapter board 20a and a second adapter board 20b, and the first adapter board 20a and the second adapter board 20b may be respectively disposed on two sides of the support portion 104. The second wiring layer 22a of the first adapter board 20a and the second wiring layer 22b of the second adapter board 20b are respectively connected to the first wiring layer 11. For example, the first pad 12 of the substrate 10 and the second pad 21 of each adapter board are correspondingly connected through a soldering process, so that the second wiring layer of each adapter board is connected to the first wiring layer.

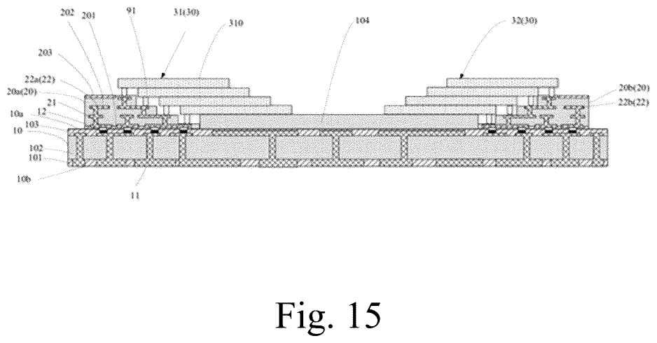

Next, as shown in FIG. 15, one or more stacks 30 are disposed on the support portion 104 of the substrate 10, and each stack comprises one or more first chips 310. For example, as shown in FIG. 15, the one or more stacks 30 comprise a first stack 31 and a second stack 32. The arrangement direction of the stack 30 and the adapter board 20 is perpendicular to the thickness direction of the substrate 10. For example, the connectors 91 are disposed between the stack 30 and the corresponding adapter board 20, and the connectors 91 are used to electrically connect the stack and the adapter board.

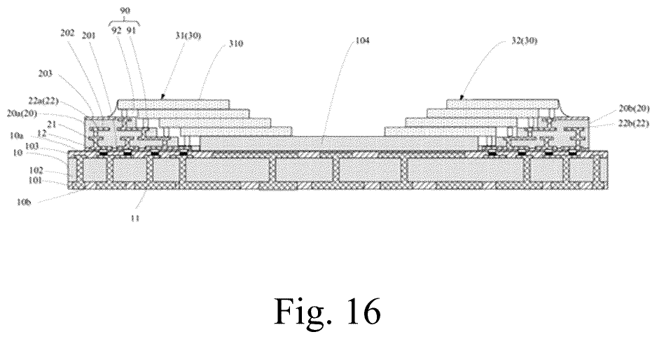

Next, as shown in FIG. 16, a filler layer 92 is formed around the connectors 91. The filler layer may function as insulation and support.

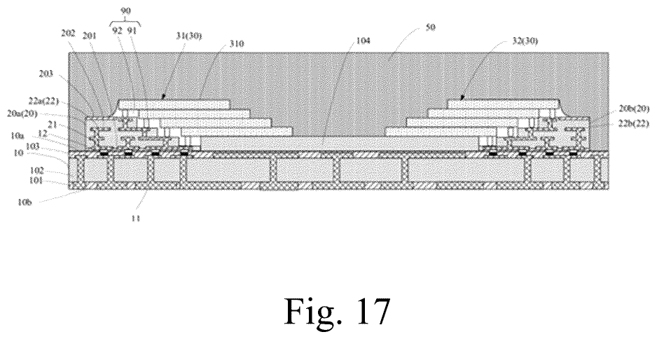

Next, as shown in FIG. 17, an encapsulation layer 50 covering the adapter board 20 and the stack 30 is formed. For example, the material of the encapsulation layer 50 comprises an epoxy molding compound or the like. For example, the epoxy molding compound may be extruded into the mold cavity and the epoxy molding compound may embed the structure shown in FIG. 16 in the mold cavity, and then the epoxy molding compound may be cured to form a structure as shown in FIG. 17.

Next, as shown in FIG. 5, a plurality of metal bumps 60 are disposed on the second side of the substrate 10. The second side is opposite to the first side. The plurality of metal bumps 60 are connected to the first wiring layer 11. For example, a plurality of metal bumps 60 are formed on the second surface 10b of the substrate 10 by a ball planting process.

So far, a manufacturing method for a packaging structure according to some other examples of the present disclosure is provided. Through the manufacturing method, a packaging structure can be formed. According to the manufacturing method, the design cycle can be shortened, the production cost is reduced, and the product yield and the product performance can be improved.

In some other examples, the manufacturing method may further comprise: disposing the second chip 70 on the first side of the substrate 10. For example, the second chip is located above the support portion 104 of the substrate 10. The second chip 70 is connected to the first wiring layer 11 in the substrate 10. Here, the second chip is a control chip.

For example, with the flip-chip structure 80, the second chip 70 is disposed on the first side of the substrate 10, and the second chip 70 is connected to the first wiring layer 11 in the substrate 10. For example, on the basis of the structure shown in FIG. 14A and FIG. 14B, in addition to disposing the stack 30 on the support portion 104 of the substrate 10, the second chip 70 may be disposed on the support portion 104 of the substrate 10 by using the flip-chip structure 80. For example, the flip-chip structure 80 comprises a fourth pad 81 and a filler layer 82. In this way, after subsequent other processes or steps, a packaging structure as shown in FIG. 6 may be formed.

So far, the packaging structure and the manufacturing method thereof according to some examples of the present disclosure are described, which can shorten the design cycle, the structure process is simple, the production cost is reduced, and the product yield and the product performance can be improved.

So far, examples of the present disclosure have been described in detail. To avoid obscuring the concepts of the present disclosure, some details known in the art are not described. Those skilled in the art can fully understand how to implement the technical solutions disclosed herein according to the above description.

Although some specific examples of the present disclosure have been described in detail by way of example, those skilled in the art should understand that the above examples are for illustration only and are not intended to limit the scope of the present disclosure. It should be understood by those skilled in the art that the above examples may be modified or equivalently replaced without departing from the scope and spirit of the present disclosure. The scope of the present disclosure is defined by the appended claims.

What is claimed is:

1. A packaging structure, comprising:
a substrate comprising a first wiring layer;
one or more adapter boards located on a first side of the substrate, each adapter board of the one or more adapter boards comprising a respective second wiring layer connected to the first wiring layer, the one or more adapter boards comprising a first adapter board; and
one or more stacks located on the first side of the substrate, each stack of the one or more stacks comprising one or more chips, the one or more stacks comprising a first stack connected to a second wiring layer in the first adapter board, wherein the one or more stacks and the one or more adapter boards are arranged along a direction perpendicular to a thickness direction of the substrate.

2. The packaging structure of claim 1, wherein:
the one or more adapter board further comprise a second adapter board, and
the one or more stacks further comprise a second stack connected to a corresponding second wiring layer in the second adapter board.

3. The packaging structure of claim 1, wherein:
the one or more stacks further comprise a second stack connected to the second wiring layer in the first adapter board.

4. The packaging structure of claim 1, wherein:
the substrate further comprises a plurality of first pads located between the first wiring layer and the one or more adapter boards and connected to the first wiring layer,
each adapter board the one or more adapter boards further comprises a plurality of second pads and a plurality of third pads, the plurality of second pads are located between the respective second wiring layer and the substrate, the plurality of second pads are connected to the respective second wiring layer and connected to the plurality of first pads, the respective second wiring layer is located between the plurality of third pads and the substrate, and the plurality of third pads are connected to the respective second wiring layer and the one or more stacks.

5. The packaging structure of claim 4, further comprising:
a first lead connected to the plurality of third pads and the one or more stacks.

6. The packaging structure of claim 1, further comprising:
an encapsulation layer covering the one or more adapter boards and the one or more stacks; and
a plurality of metal bumps located on a second side of the substrate and connected to the first wiring layer, wherein the second side is opposite to the first side along the thickness direction of the substrate.

7. The packaging structure of claim 1, wherein the one or more adapter boards comprise a printed circuit board, an interposer, or another substrate.

8. A packaging structure, comprising:
a substrate comprising a first wiring layer;
one or more adapter boards located on a first side of the substrate, each adapter board of the one or more adapter boards comprising a respective second wiring layer connected to the first wiring layer, the one or more adapter boards comprising a first adapter board;
one or more stacks located on the first side of the substrate, each stack of the one or more stacks comprising one or more first chips, the one or more stacks comprising a first stack connected to the second wiring layer in the first adapter board, wherein the one or more stacks and the one or more adapter boards are arranged along a direction perpendicular to a thickness direction of the substrate; and
a second chip connected to a second wiring layer in the first adapter board, wherein the first adapter board is located between the second chip and the substrate.

9. The packaging structure of claim 8, wherein:
the one or more adapter board further comprise a second adapter board, and
the one or more stacks further comprise a second stack connected to a corresponding second wiring layer in the second adapter board.

10. The packaging structure of claim 8, wherein:
the one or more stacks further comprise a second stack connected to the second wiring layer in the first adapter board.

11. The packaging structure of claim 8, wherein:
the substrate further comprises a plurality of first pads located between the first wiring layer and the one or more adapter board boards and connected to the first wiring layer,
each adapter board of the one or more adapter boards further comprises a plurality of second pads and a plurality of third pads, the plurality of second pads are located between the respective second wiring layer and the substrate, the plurality of second pads are connected to the respective second wiring layer and connected to the plurality of first pads, the respective second wiring layer is located between the plurality of third pads and the substrate, and the plurality of third pads are connected to the respective second wiring layer and the one or more stacks.

12. The packaging structure of claim 11, further comprising:
a first lead connected to the plurality of third pads and the one or more stacks.

13. The packaging structure of claim 8, further comprising:
a second lead connected to the second chip and the second wiring layer in the first adapter board.

14. The packaging structure of claim 8, further comprising:
a flip-chip structure located between the second chip and the first adapter board and connected to the second chip and the second wiring layer in the first adapter board.

15. The packaging structure of claim 14, wherein the flip-chip structure comprises:
a fourth pad located between the second chip and the second wiring layer in the first adapter board; and
a filler layer filled around the fourth pad.

16. The packaging structure of claim 8, further comprising:
an encapsulation layer covering the one or more adapter boards, the one or more stacks, and the second chip; and
a plurality of metal bumps located on a second side of the substrate and connected to the first wiring layer, wherein the second side is opposite to the first side along the thickness direction of the substrate.

17. The packaging structure of claim 8, wherein:
the first chip is a memory chip, and
the second chip is a control chip.

18. A manufacturing method for a packaging structure, comprising:
obtaining a substrate and one or more adapter boards, wherein the substrate comprises a first wiring layer, each adapter board of the one or more adapter boards comprises a respective second wiring layer, and the one or more adapter boards comprise a first adapter board;
disposing the one or more adapter boards on a first side of the substrate, wherein the respective second wiring layer of each adapter board of the one or more adapter boards is connected to the first wiring layer;
disposing one or more stacks on a first side of the substrate, each stack of the one or more stacks comprising one or more first chips, the one or more stacks comprising a first stack, wherein the one or more stacks and the one or more adapter boards are arranged along a direction perpendicular to a thickness direction of the substrate; and
connecting the first stack to a second wiring layer in the first adapter board.

19. The manufacturing method of claim 18, wherein connecting the first stack to the second wiring layer in the first adapter board comprises:
connecting the first stack to the second wiring layer in the first adapter board using a first lead,
wherein the manufacturing method further comprises:
disposing a second chip on a side of the first adapter board away from the substrate, and
connecting the second chip to the second wiring layer of the first adapter board by connecting the second chip to the second wiring layer of the first adapter board using a second lead or a flip-chip structure.

20. The manufacturing method of claim 18, further comprising:
forming an encapsulation layer covering the one or more adapter boards and the one or more stacks; and
disposing a plurality of metal bumps on a second side of the substrate, wherein the plurality of metal bumps are connected to the first wiring layer, and the second side is opposite to the first side along the thickness direction of the substrate.
